(19) United States
(12) Patent Application Publication
(10) Pub. No.: US 2014/0231809 A1
(43) Pub. Date: Aug. 21, 2014

(54) METHODOLOGY FOR FABRICATING ISOTROPICALLY RECESSED SOURCE REGIONS OF CMOS TRANSISTORS

(71) Applicants: Nicholas C. Fuller, North Hills, NY (US); Steve Koester, Minneapolis, MN (US); Isaac Lauer, Mahopac, NY (US); Ying Zhang, Yorktown Heights, NY (US)

(72) Inventors: Nicholas C. Fuller, North Hills, NY (US); Steve Koester, Minneapolis, MN (US); Isaac Lauer, Mahopac, NY (US); Ying Zhang, Yorktown Heights, NY (US)

(73) Assignee: INTERNATIONAL BUSINESS MACHINES CORPORATION, Armonk, NY (US)

(21) Appl. No.: 13/565,030

(22) Filed: Aug. 2, 2012

Related U.S. Application Data
(62) Division of application No. 12/779,079, filed on May 13, 2010.

(51) Int. Cl. H01L 29/786

(52) U.S. Cl. CPC H01L 29/78675
USPC 257/66

(57) ABSTRACT

A Field Effect Transistor device includes a buried oxide layer, a silicon layer above the buried oxide layer, an isotropically recessed source region, and a gate stack comprising a gate dielectric, a conductive material, and a spacer.

### CROSS REFERENCE TO RELATED APPLICATIONS

This is a divisional application of application Ser. No. 12/779,079, filed May 13, 2010, which is incorporated by reference herein.

This application is related to co-pending application docket number YOR920100137US1, serial No. 12/779,087, entitled “METHODOLOGY FOR FABRICATING ISOTROPICALLY RECESSED DRAIN REGIONS OF CMOS TRANSISTORS;” and co-pending application docket number YOR920100138US1, Ser. No. 12/779,100, entitled “METHODOLOGY FOR FABRICATING ISOTROPICALLY RECESSED SOURCE AND DRAIN REGIONS OF CMOS TRANSISTORS;” the entire contents of each of which are incorporated herein by reference.

This invention was made with Government support under FA8650-08-C-7806 awarded by the Defense Advanced Research Projects Agency (DARPA). The Government may have certain rights to this invention.

### BACKGROUND

The present invention generally relates to integrated circuits (ICs), and more particularly to CMOS, NFET and PFET devices.

Generally, semiconductor devices include a plurality of circuits which form an integrated circuit including chips, thin film packages and printed circuit boards. Integrated circuits can be useful for computers and electronic equipment and can contain millions of transistors and other circuit elements that are fabricated on a single silicon crystal substrate.

### SUMMARY

According to an aspect of the present invention, a Field Effect Transistor device includes a buried oxide layer, a silicon layer above the buried oxide layer, an isotropically recessed source region, and a gate stack comprising a gate dielectric, a conductive material, and a spacer.

### BRIEF DESCRIPTION OF THE SEVERAL VIEWS OF THE DRAWINGS

Preferred embodiments of the present disclosure are described below with reference to the drawings, which are described as follows:

FIG. 1 is a cross section view of a partially fabricated FET device showing lithography to protect the source region.

FIG. 2 is a cross section view of a partially fabricated FET device showing a 1st stage of the inventive processing sequence with native oxide removal through a “breakthrough” etch process to form a recess in the source region.

FIG. 3 is a cross section view of a partially fabricated FET device showing a 2nd stage of the inventive processing sequence subsequent to a deposition of a metallic or inorganic material atop the horizontal surface of the recess in the source region.

FIG. 4 is a cross section view of a partially fabricated FET device showing a 3rd stage of the inventive processing sequence subsequent to a lateral etch of the recess channel to the target distance in the source region.

FIG. 5 is a cross section view of a partially fabricated FET device showing a 4th stage of the inventive processing sequence subsequent to the removal of the passivating layer and a vertical etch in the recess to the target depth in the the source region.

FIG. 6 is a cross section view of an embodiment of the invention showing a fabricated FET device.

### DETAILED DESCRIPTION

As device scaling continues to enable density scaling and lower energy consumption per operation, CMOS devices with low operational voltages, multiple gates, and ultra thin body are being considered and developed.

Such changes would enable improved short channel effect (SCE) and reduced variability of the threshold voltage (Vt) for turning on the transistor. Performance enhancing elements previously introduced (eSiGe for PFETs) and targeted for future technology nodes (eSiC for NFETs) would likely still be employed for 22 nm and beyond technologies to enhance device performance.

As device geometries change for such nodes—incorporating multi-gates and reducing the channel thickness (much less than 40 nm) for the aforementioned reasons—the ability to controllably recess the channel during patterning for the fabrication of the source regions of the transistor to enable subsequent eSiGe, eSiC etc is significantly reduced.

This issue is further exacerbated for ultra steep subthreshold-slope devices which operate on the principle of band-to-band tunneling as in the case of a subthreshold slope less than 60 mV/decade and employed bias voltages much less than 1V. In these devices the source region must be recessed in both horizontal and vertical directions on a thin body, such as less than or equal to 40 nm, channel to enable subsequent growth of SiGe or other relevant material.

Conventional plasma etching processes typically employed for recessing source regions are not suitable at these dimensions, since the channel thickness, for example, SOI, GOI, SGOI, is less than or equal to 40 nm. The intrinsic ion energy with no applied bias power typically found in a low pressure plasma process is less than or equal to 15V. Thus, the controllability of the isotropic etch process used to repeatedly fabricate recessed source regions is significantly reduced. Less reactive gaseous species such as HBr, C12, and BC13 and gas dilution such as via insertion of inert gases such as He, Ar etc can reduce the etch rate and may increase controllability to some degree versus conventional CHF3, CF4, SF6-containing chemistries but still do not produce the required degree of control.

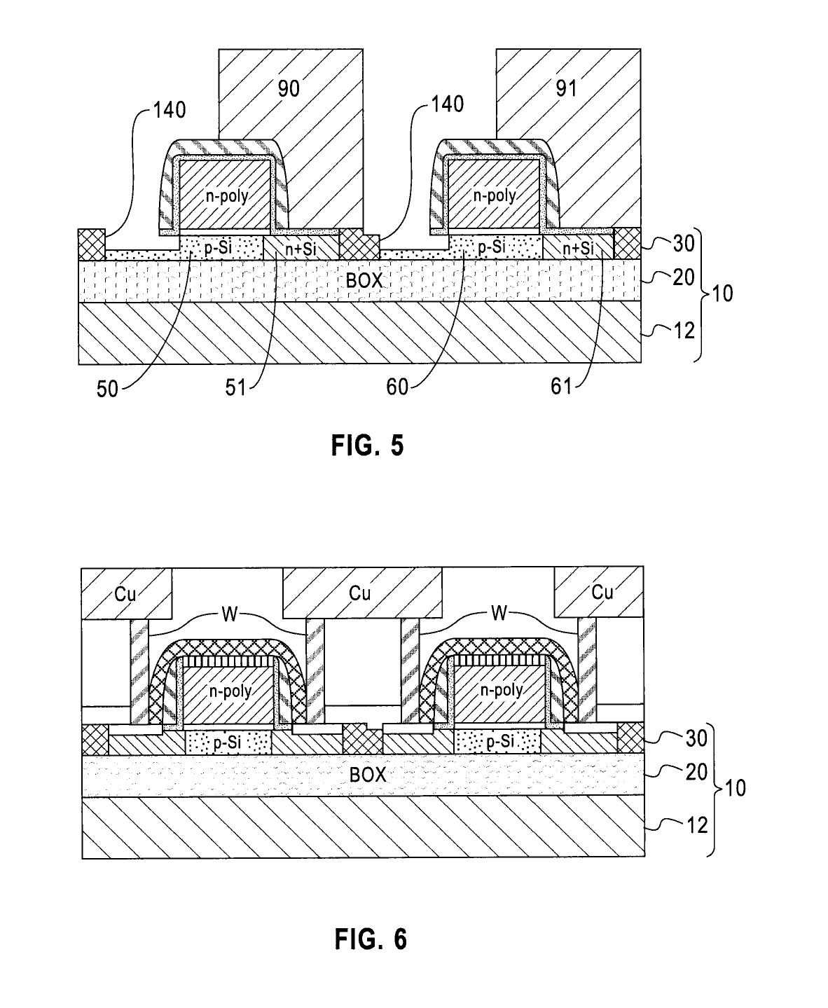

To this end, the use of a sequence of etch and deposition processes as shown in FIGS. 2 through 5 to recess a source region of a device to the required specification is employed. Without loss of generality, a sub-threshold slope voltage device in which the target recess for the source region for subsequent epitaxial growth of SiGe is approximately 40 nm whereby the recess extends an equivalent distance beneath the gate as depicted in FIG. 5.

The inventive process first employs a known etch process on a typical medium to high density plasma configuration (inductively coupled plasma (ICP), electron cyclotron resonance ECR), dual frequency capacitive (DFC), helicon, or radial line slot antenna (RLSA) with typical plasma conditions, for example, pressure: much less than 10 mT; bias power: 15 W-150 W; source power: less than or equal to 1 kWs; gases: CF4, CHF3, CH2F2, CH3F, SF6, C12, and/or HBr—containing chemistries, to “breakthrough” the native oxide layer and recess a few nm (less than 10 nm) into the channel as shown in FIG. 2.

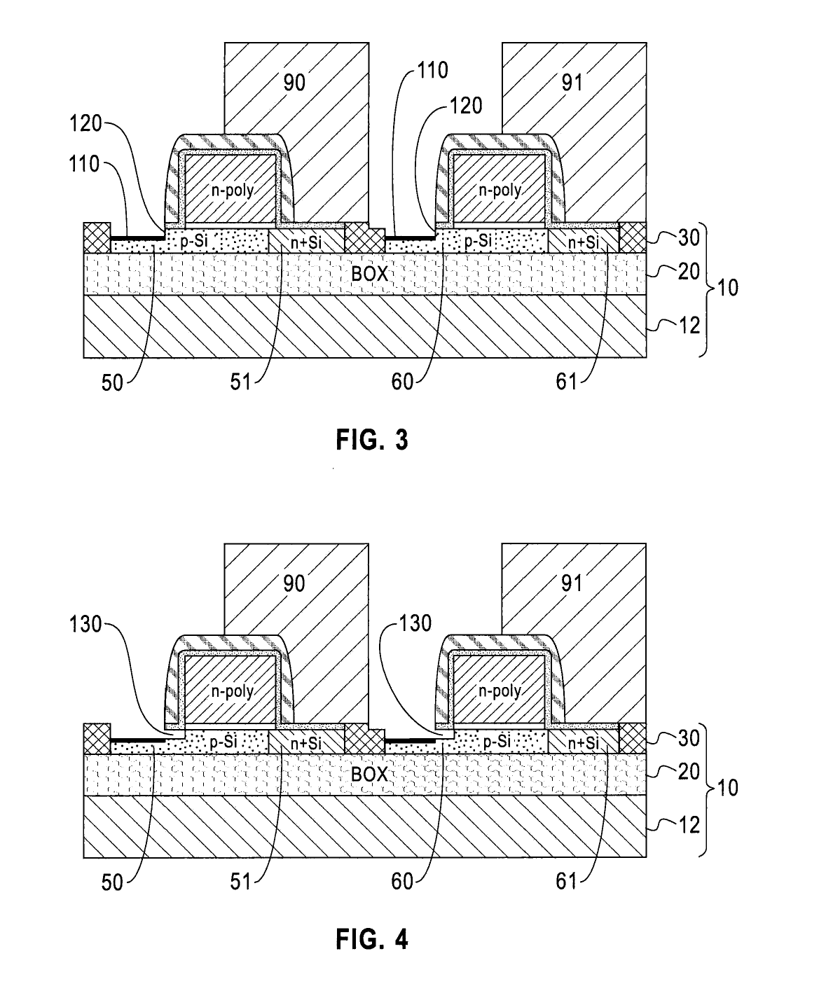

At this stage of the inventive process, a selective deposition process is employed to passivate the horizontal surfaces as shown in FIG. 3. Such a process can be a physical vapor deposition (PVD) process or another appropriate technique, depositing a few monolayers of a metallic Ti, Ta, TiN, TaN, TiO, TaO, or an inorganic film, such as, SiO2, SiON, Si3N4, atop only the horizontal channel surfaces leaving the vertical surfaces of the channels exposed.

With the horizontal surfaces passivated, an isotropic etch process, conducted on the same or different platform for that used for the breakthrough process in the first step comprised of SF6, C12, HBr, CH3F, CH2F2, CHF3, and/or CF4-containing chemistries can be applied to laterally etch the channel to the target dimension as in FIG. 4.

Typical conditions applied for such a process include: pressure greater than or equal to 10 mT, bias power equal to 0 W, gases as detailed above, and source powers less than or equal to 1 kWs. Since there is no applied bias power, the intrinsic ion energy of this discharge, which is less than or equal to 15V, is less than the energy required to break the bonds in Ti, Ta, TiN, TaN, SiO2, SiON, Si3N4 etc and so the horizontal surface remains passivated while laterally etching the exposed vertical surface.

Once the lateral etch recess is completed, the passivating layers are removed and the target vertical etch depths are achieved as in FIG. 5. This can be done by use of a known etch process carefully tuned so as to remove the passivating layers and achieve the target depths. Subsequent processing can be conducted to achieve epitaxial growth of the SiGe or other appropriate layer to fabricate the device shown in FIG. 6.

Accordingly, an embodiment of the invention provides an aggressively scaled CMOS device in which the source regions comprised of different materials from that of the employed channel are recessed by a sequence of etch and deposition processes, such as, etch deposition etch.

This sequence further provides a CMOS device enabling higher speed circuits and ring oscillators as well as an aggressively scaled CMOS device in which a bias-free, fluorine or fluorine and chlorine-containing etch chemistry is employed to laterally etch the channel selective to the employed spacer and passivating layer of the channel.

This embodiment of the invention further provides an aggressively scaled CMOS device in which the recess of the source region is equidistant in both horizontal and vertical directions, that is, much less than 40 nm, as well as an aggressively scaled

CMOS device in which a passivating layer comprised of a few monolayers of a metallic, such as, Ti, Ta, TiN, TaN, TiO, TaO, or an inorganic, such as, SiO2, SiON, Si3N4, film is deposited only onto the horizontal surface of the exposed channel.

There is provided an aggressively scaled CMOS device in which the source region is recessed by a sequence of etch and deposition processes; facilitating subsequent epitaxial growth of materials in the region different from that of the channel and, thus, enabling faster speed integrated circuits and ring oscillators.

The present embodiment is directed to an aggressively scaled CMOS device in which an inventive processing sequence of etching, deposition, followed up by etching is used to recess source regions of thin body devices, for example, channel thickness less than or equal to 40 nm, in a controllable manner facilitating subsequent growth of alternative materials, such as, eSiGe and eSiC, in these regions, thus enabling enhanced carrier mobility and higher speed integrated circuits and ring oscillators.

To achieve improved short channel effect and reduced Vt variability, thinner body, for example, less than or equal to 40 nm, and multi-gated devices are being considered for 22 nm and beyond technology nodes. The ability to fabricate source regions of materials different from that employed for the channel correlates quite strongly with the ability to controllably recess the channel, such as, SOI, GOI, and SGOI. Thus, for even thinner body devices, extreme control is needed for recessing source regions to enable subsequent formation of the same.

Conventional plasma etching processes used for recessing larger features for larger ground rule devices are incapable of achieving the desired degree of control required for feature sizes at the 22 nm node dimensions and beyond. In contrast, the present invention provides the use of a sequence of etch, deposition, and etching processes to recess/fabricate these source regions of the device.

The 1st stage entails use of a known etching process to breakthrough the native oxide layers of the channel. This is achieved in standard CF4, CHF3, CH2F2, CH3F, SF6, C12, and/or HBr—containing chemistries. This step is followed up by a depositing a few monolayers of a metallic, such as, Ti, Ta, TiN, TaN, TiO, TaO, or an inorganic film, such as, SiO2, SiON, Si3N4, atop only the horizontal surfaces of the channel. In this way the latter surfaces are protected while exposing the vertical surfaces for subsequent modification.

A lateral etch process is subsequently used to laterally etch the exposed vertical surfaces of the channel to the target distance employing bias free SF6, C12, HBr, CH3F, CH2F2, CHF3, and/or CF4-containing plasma process.

The final step entails removal of the passivating layers and etching the channels in a vertical direction only using an anisotropic etch process, such as, high bias power; CF4, CHF3, CH2F2, CH3F, SF6, C12, and/or HBr—containing plasma.

The recessed region of the source is now ready for subsequent epitaxial growth of SiGe, SiC, or other appropriate layer to enable enhanced device/ring oscillator performance.

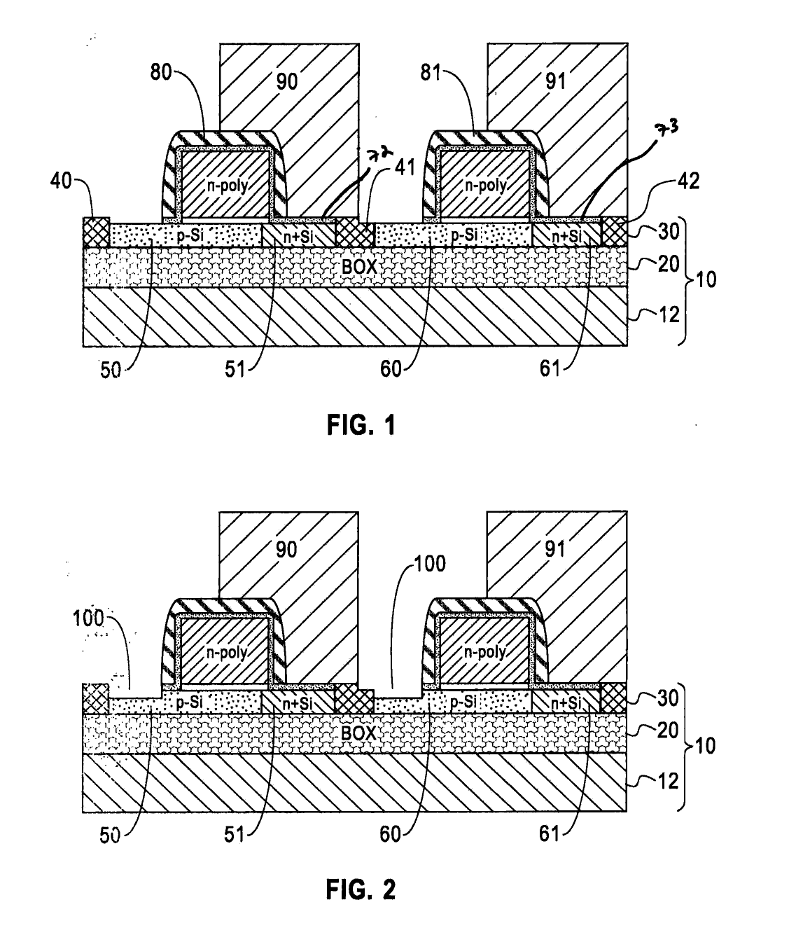

Referring to the drawings, FIG. 1 is a cross section view of a partially fabricated FET device with the drain regions protected and with native oxide removed to expose a portion of silicon regions 50 and 60 prior to commencing source recess.

A silicon on insulator substrate 10 including a substrate 12, a buried oxide layer 20 and silicon layer 30 over the buried oxide 20 is shown. Shallow trench isolation regions 40, 41, and 42 are formed in silicon layer 30 to provide isolated silicon regions 50 and 60.

Drain regions 51 and 61 respectively have a native oxide layer 72 and 73 thereover. Photoresists 90 and 91 are formed over portions of gate stacks 80 and 81, shallow trench isolation regions 41 and 42, and oxide layers 72 and 73 over drain regions 51 and 61. The gate stacks may include a gate dielectric such as SiON or a higher dielectric, a conductive material, and a spacer.

FIG. 2 is a cross section view of a partially fabricated FET device illustrating an etch step. The process employs a prior art etch process on a typical medium to high density plasma configuration with typical plasma conditions. Typical medium to high density plasma configurations can include inductively coupled plasma (ICP), electron cyclotron resonance (ECR), dual frequency capacitive (DFC), Helicon, or Radial Line Slot Antenna (RLSA). Typical plasma conditions can include pressure less than or equal to 10 mT, bias power 15-150 W, source power less than or equal to 1 kWs and F, Br or Cl containing gases to re-breakthrough the native oxide layer. The recess 100 is less than 10 nm into the channel.

FIG. 3 is a cross section view of a partially fabricated FET device illustrating a passivating layer 110. Passivating layer 110 can be formed by a physical vapor deposition (PVD) process or similarly appropriate technique depositing a few layers of a metallic or inorganic film atop only the horizontal. The vertical surface 120 of the channel remains exposed. Examples of a metallic film can include films containing Ti, Ta, TiN, TiO, and TaO. Examples of inorganic films include SiO2, SiON, Si3N4.

FIG. 4 is a cross-sectional view of a partially fabricated FET device illustrating a lateral etch. An isotropic etch process is performed to laterally etch the channel to a target dimension 130. The isotropic etch process can be conducted on the same or different platform as that used for the breakthrough process of FIG. 2. The etch process can utilize F, Br or Cl containing gases.

Typical conditions include pressure greater than or equal to 10 mT, bias power equal to 0 W; F, Br or Cl containing gases, and source powers less than or equal to 1 kWs. Since bias power equals 0 W, the intrinsic ion energy of this discharge, less than or equal to 15V is much less than the energy required to break the bonds of the passivated horizontal surface 110 in FIG. 3, and therefore the horizontal surface remains passivated while the exposed vertical surface 120 is laterally etched.

FIG. 5 is a cross section view of a partially fabricated FET device illustrating a larger recess formed by a vertical etch step. Passivating layer 110 is removed and the target vertical etch depth 140 is achieved. The etch process to achieve the desired vertical etch depth will be understood by those of ordinary skill in the art.

FIG. 6 shows an example of a device that can be fabricated by the above method.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A Field Effect Transistor device, comprising:
a buried oxide layer;
a silicon layer above the buried oxide layer;
an isotropically recessed source region; and
a gate stack comprising a gate dielectric, a conductive material, and a spacer.

2. The device of claim 1, further comprising:
the isotropically recessed source region adjacent and underneath the gate stack.

3. The device of claim 1, wherein the silicon layer further comprises shallow trench isolation regions to provide isolated silicon regions.

4. The device of claim 1, wherein the silicon layer comprises p or n-doped polysilicon.

5. The device of claim 1, wherein the source region is formed by n+doping the silicon layer.

6. The device of claim 1, wherein the source region is formed by p+doping the silicon layer.

7. The device of claim 1, wherein a gate dielectric is formed on the silicon region and the gate stack is formed over the gate dielectric.

8. The device of claim 1, wherein the gate stack comprises:
doped polysilicon;
a conformal layer of native oxide; and
a layer of silicon nitride or other dielectric over the gate native oxide.

9. The device of claim 1, wherein a portion of the source region further comprises a native oxide layer.

10. The device of claim 9, wherein a photoresist is formed over portions of the gate stack, a shallow trench isolation region, the source region, and the native oxide layer.
